(19) United States
(12) Patent Application Publication
(10) Pub. No.: US 2004/0115887 A1
(43) Pub. Date: Jun. 17, 2004

(54) NON-VOLATILE MEMORY STRUCTURE AND METHOD OF FABRICATING THE SAME

(76) Inventor: Ching-Yu Chang, Yilan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,142

(22) Filed: Mar. 19, 2003

(30) Foreign Application Priority Data
Dec. 16, 2002 (TW) 91136248

(51) Int. Cl. H01L 21/8234

(52) U.S. Cl. 438/275

(57) ABSTRACT

A method of fabricating a non-volatile memory. A long dielectric strip is formed over a substrate and then a buried bit line is formed in the substrate on each side of the long dielectric strip. The long dielectric strip is patterned to form a plurality of dielectric blocks. Thereafter, a code-masking layer that exposes some dielectric blocks is formed over the substrate. Using the code-masking layer an etching mask, the exposed dielectric blocks are removed. The code-masking layer is removed and a gate dielectric layer is formed over the substrate. Finally, a word line is formed over the substrate.

### CROSS REFERENCE TO RELATED APPLICATIONS

This application claims the priority benefit of Taiwan application serial no. 91136248, filed Dec. 16, 2002.

### BACKGROUND OF INVENTION

1. Field of the Invention

The present invention relates to a non-volatile memory structure and method of fabricating the same. More particularly, the present invention relates to a mask read-only-memory structure and method of fabricating the same.

2. Description of Related Art

Most mask read-only-memory (mask ROM) has a structure that includes a plurality of bit lines (BL) and a plurality of word lines (WL) that cross over the bit lines. Underneath the word lines and between two neighboring bit lines, there is a memory cell channel region. For some mask ROM, a data value of “1” or “0” is stored according to whether ions are implanted into the channel layer or not. The process of implanting ions into the specified channel regions is often referred to as a code implant process.

The code implant process of a mask ROM includes patterning a photoresist layer on a substrate using a photomask to expose the code implant regions and then conducting an ion implantation to implant ions into the designated regions using the patterned photoresist layer as a mask. However, the photomask that serves as a coding mask in the code implant process may contain single isolated patterns as well as dense patterns. During the transfer of pattern to the photoresist by photo-exposure, intensity of illumination on single isolated patterns will be weaker than intensity of illumination on dense patterns. Hence, deviation in critical dimension between dense pattern regions and isolated pattern regions due to optical proximity effect (OPE) can be considerable. Therefore, the code implant regions in the mask ROM may have non-uniform dimension leading to a misalignment of implanted ions in the channel implant process. Ultimately, wrong data may be programmed into the read-only-memory cells.

To reduce the difference in critical dimension in the mask ROM due to coexistence of dense and isolated pattern regions within the same photomask, technique such as an optical proximity correction (OPC) or a phase shift mask (PSM) is deployed. The optical proximity correction method utilizes a complementary pattern design to eliminate critical dimension deviation caused by proximity effect. However, to deploy the OPC method, a photomask with specialized pattern must be designed. Thus, aside from spending more time to fabricate the photomask, the photomask is more difficult and costly to fabricate. Furthermore, debugging any defects on the photomask pattern after fabrication is very difficult.

In addition, if the coding mask used for coding implant is misaligned or contains some deviation in critical dimension, coding ions originally intended for the designated implant regions may diffuse into the buried bit lines leading to a change in ion concentration. Consequently, there may be a considerable reduction in the current flowing through the buried bit line.

### SUMMARY OF INVENTION

Accordingly, one object of the present invention is to provide a mask read-only-memory (mask ROM) structure and method of fabricating the same that prevents coding ions from diffusing into a buried bit line and leads to a considerable reduction in current flowing through the buried bit line during operation.

A second object of this invention is to provide a mask read-only-memory structure and a method of fabricating the same that prevents the production of non-uniform critical dimensions in a code implant region having both isolated patterns and dense patterns after memory coding using a conventional code implant process.

A third object of this invention is to provide a mask read-only-memory structure and a method of fabricating the same capable of coding the mask ROM with great precision without using optical proximity or phase shift mask technique, thereby lowering cost of production.

To achieve these and other advantages and in accordance with the purpose of the invention, as embodied and broadly described herein, the invention provides a method of fabricating non-volatile memory. First, a long dielectric strip is formed over a substrate. A buried bit line is formed in the substrate on each side of the long dielectric strip. Thereafter, the long dielectric strip is patterned in a direction perpendicular to the buried bit lines so that a plurality of dielectric blocks is produced. A code-masking layer is formed over the substrate. The code-masking layer includes an opening for an isolated pattern region and an opening for a dense pattern region that exposes a portion of the dielectric blocks. Due to optical proximity effect, deviation of critical dimensions occurs in the opening of the isolated pattern region as well as the dense pattern region. Using the code-masking layer as an etching mask, the exposed dielectric blocks are removed. The exposed dielectric blocks are removed by conducting anisotropic etching. Although the critical dimension of the opening in the code-masking layer is non-uniform, the ultimately formed memory device in this invention is little affected by the non-uniform critical dimension because the anisotropic etching step removes the dielectric blocks smoothly and completely. After removing the code-masking layer, a gate dielectric layer formed over the substrate. The gate dielectric layer has a thickness that differs from the dielectric blocks. Thereafter, a word line is formed over the substrate. The word line crosses over the buried bit lines and forms a plurality of coding memory cells. Among these coding memory cells, the ones having a dielectric block is in a first logic state and the ones having a gate dielectric layer is in a second logic state.

This invention also provides a non-volatile memory structure. The non-volatile memory includes a substrate, a buried bit line, a plurality of dielectric blocks, a gate dielectric layer and a word line. The buried bit line is embedded within the substrate. The dielectric blocks are positioned on the substrate and the gate dielectric layer is positioned on the substrate away from the dielectric blocks. The word line crosses over the buried bit line to constitute a plurality of coding memory cells. Among the coding memory cells, the ones having a dielectric block is in a first data state and the ones having a gate dielectric layer is in a second data state.

The mask ROM coding method according to this invention utilizes the difference in thickness between a dielectric block and a gate dielectric layer instead of a conventional code implant process to code the memory device. Hence, non-uniform dimensions in the code implant region within a memory device caused by a non-uniformity of critical dimensions between the isolated pattern region and the dense pattern region within a code-masking layer is prevented.

Because the mask ROM coding method according to this invention is not based on the conventional code implant process, the diffusion of coding ions into the buried bit line will not occur. In other words, current reduction within the buried bit line due the diffusion of coding ions no longer is a problem in this invention.

Furthermore, two sets of photomask designs each having a different line/pitch pattern are used to form a plurality of dielectric blocks. Hence, dimension of the dielectric blocks can be reduced to about 0.12 μm. In other words, critical dimension of the memory device can be reduced to about 0.12 μm.

Since the coding process according to this invention does not involve the use of complicated optical proximity correction or phase shift mask technique, cost for producing mask ROM is reduced considerably.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1F are perspective sectional views showing the progression of steps for producing a mask ROM according to one preferred embodiment of this invention; and

FIG. 2 is a top view of the openings on the code masking layer in FIG. 1C.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

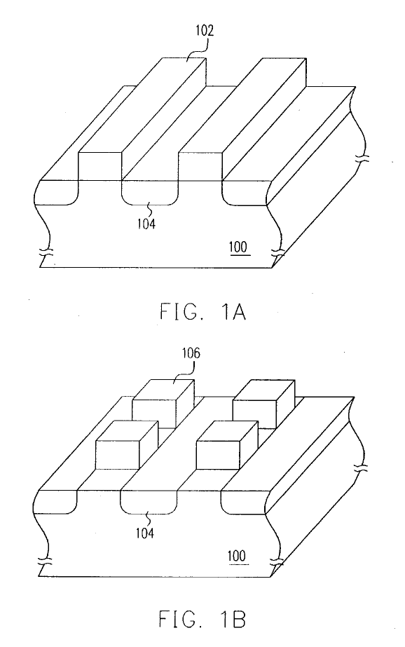

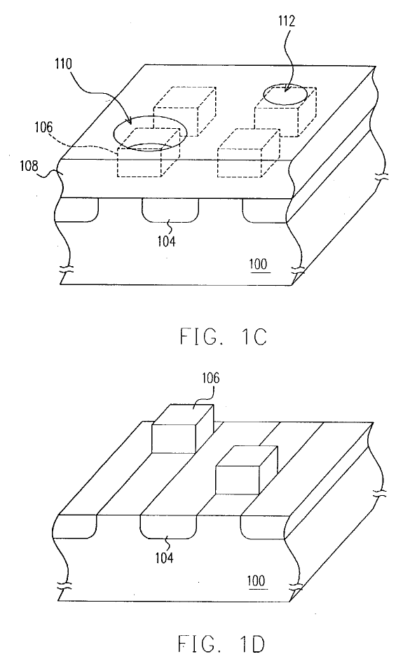

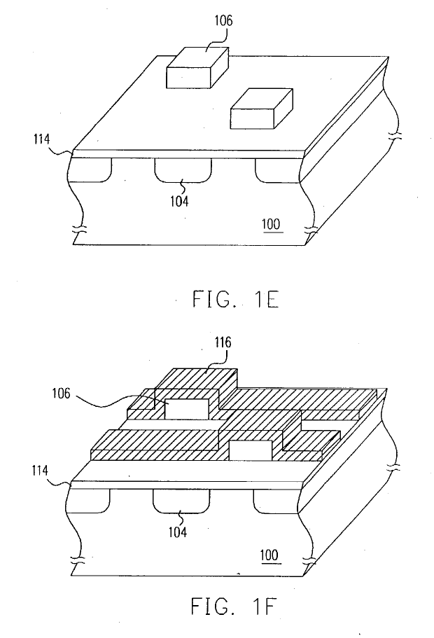

FIGS. 1A to 1F are perspective sectional views showing the progression of steps for producing a mask ROM according to one preferred embodiment of this invention. As shown in FIG. 1A, a long dielectric strip 102 is formed over a substrate 100. The substrate 100 is a p-type silicon substrate and the long dielectric strip 102 is a strip of silicon oxide material, a step of silicon nitride material or a strip of silicon oxy-nitride material, for example. The long dielectric strip 102 is formed, for example, by deposition dielectric material over the substrate 100 in a chemical vapor deposition process and then patterning the dielectric layer in photolithographic and etching processes.

Thereafter, using the long dielectric strip 102 as an implantation mask, an ion implantation is carried out to form a buried bit line 104 in the substrate 100 on each side of the long dielectric strip 102. The buried bit line 104 is an n-doped region, for example. Because the long dielectric strip 102 serves as an implantation mask for the buried bit line 104, the buried bit line 104 is self-aligned.

As shown in FIG. 1B, the long dielectric strip 102 is patterned in a direction perpendicular to the buried bit line 104 to form a plurality of dielectric blocks 106. The long dielectric strip 102 is patterned, for example, by conducting photolithographic and etching process. Note that the dielectric blocks 106 are patterned out using two sets of photomask each having a different line/pitch pattern. Hence, each dielectric block 106 having sides as small as 0.12 μm can be fabricated using a single light source 248 to carry out the exposure.

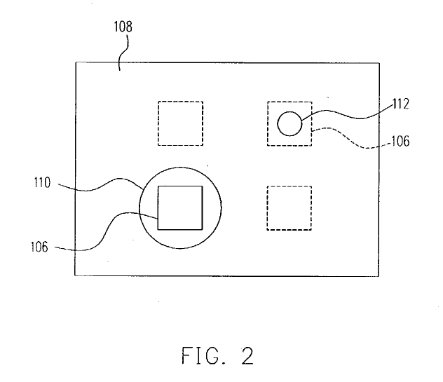

As shown in FIG. 1C, a code-masking layer 108 is formed over the substrate 100. The code masking layer 108 a dense pattern region opening 110 and an isolated pattern region opening 112. The openings 110 and 112 expose a portion of the dielectric blocks 106. FIG. 2 is a top view of the openings on the code-masking layer in FIG. 1C. In the process of forming the code-masking layer 108, the illumination of the isolated pattern region is weaker than the dense pattern region during photo-exposure. Hence, there will be deviation in the critical dimensions due to optical proximity effect between the dense pattern region opening 110 and the isolated pattern region opening 112 leading to a non-uniform opening dimension.

Thereafter, using the code-masking layer 108 as an etching mask, an anisotropic etching operation is carried out to remove the exposed dielectric blocks 106. The anisotropic etching operation can be a dry etching process (etching with gaseous reactants) or a wet etching process (etching with liquid reactants). In this embodiment, the anisotropic etching reaction is carried out using a reactant such as buffered oxide etchant (BOE), hydrofluoric acid (HF) or hot phosphoric acid.

Although the critical dimensions of the openings 110 and 112 of the code-masking layer 108 are rarely uniform, it has little effect on the coding of memory device in this invention. This is because the coding of memory device is achieved based on the removal of a portion of the dielectric blocks 106 in an anisotropic etching operation rather than a conventional code implant process.

Note also that even if the dielectric block 106 under the isolated pattern region opening 112 is only partially exposed, the dielectric block 106 exposed by the opening 112 can still be removed completely because the dielectric blocks 106 are removed by conducting anisotropic etching. Furthermore, even if,the dense pattern region opening 112 exposes some of the surrounding substrate besides the dielectric block 106, there will be no serious effect on the mask ROM of this invention because of an etching selectivity between the dielectric block 106 and the substrate 100.

As shown in FIGS. 1D and 1E, the code-masking layer 108 is removed to expose the substrate 100 and the remaining dielectric blocks 106. Thereafter, a gate dielectric layer 114 is formed over the substrate 100. The gate dielectric layer 114 is formed, for example, by conducting a thermal oxidation to transform the uppermost layer of silicon in the substrate 100 into an oxide layer. The gate oxide layer 114 has a thickness different from the dielectric blocks 106. For example, the gate dielectric layer 114 may have a thickness considerably less than the thickness of the dielectric block 106 so that data states in the memory device can be distinguished. In this embodiment, the gate dielectric layer 114 has a thickness between about 50 Å to 90 Å while the dielectric blocks has a thickness between about 120 Å to 160 Å, for example.

As shown in FIG. 1F, a word line 116 is formed over the substrate 100. The word line 116 crosses over the buried bit line 104 to form a plurality of code memory cells. Among the code memory cells, the ones having a dielectric block is in a first data state due to a larger threshold voltage of operation and the ones having a gate dielectric layer 114 is in a second data state due to a lower threshold voltage of operation.

The mask read-only-memory (mask ROM) structure according to this invention includes a substrate 100, a buried bit line 104, a plurality of dielectric blocks 106, a gate dielectric layer 114 and a word line 116.

The mask ROM coding method according to this invention utilizes the difference in thickness between a dielectric block and a gate dielectric layer instead of a conventional code implant process to code the memory device. Hence, non-uniform dimensions in the code implant region within a memory device caused by a non-uniformity of critical dimensions between the isolated pattern region and the dense pattern region within a code-masking layer is prevented.

Because the mask ROM coding method according to this invention is not based on the conventional code implant process, the diffusion of coding ions into the buried bit line will not occur. In other words, current reduction within the buried bit line due the diffusion of coding ions no longer is a problem in this invention.

Furthermore, two sets of photomask designs each having a different line/pitch pattern are used to form a plurality of dielectric blocks. Hence, dimension of the dielectric blocks can be reduced to about 0.12 μm. In other words, critical dimension of the memory device can be reduced to about 0.12 μm.

Since the coding process according to this invention does not involve the use of complicated optical proximity correction or phase shift mask technique, cost for producing mask ROM is reduced considerably.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of fabricating a non-volatile memory, comprising the steps of:
providing a substrate;
forming a long dielectric strip over the substrate;
forming a buried bit line in the substrate on each side of the long dielectric strip;
patterning the long dielectric strip to form a plurality of dielectric blocks;
forming a code-masking layer over the substrate so that some of the dielectric blocks are exposed;
removing the exposed dielectric blocks using the code-masking layer as an etching mask;
removing the code-masking layer;
forming a gate dielectric layer over the substrate; and
forming a word line over the substrate.

2. The method of claim 1, wherein the gate dielectric layer has a thickness different from the one of the dielectric blocks.

3. The method of claim 1, wherein the gate dielectric layer has a thickness smaller than the one of the dielectric blocks.

4. The method of claim 1, wherein material constituting the long dielectric strip is selected from a group consisting of silicon nitride, silicon oxide and silicon oxy-nitride.

5. The method of claim 1, wherein the exposed dielectric blocks are removed in an anisotropic etching process.

6. The method of claim 1, wherein the anisotropic etching process includes a wet etching or a dry etching.

7. The method of claim 1, wherein the step of forming the buried bit line includes conducting an ion implantation using the long dielectric strip as an implantation mask.

8. A non-volatile memory structure, comprising:
a substrate;
a buried bit line in the substrate;
a plurality of dielectric blocks on the surface of the substrate;
a gate dielectric layer over the substrate; and
a word line crossing over the buried bit line to form a plurality of code memory cells, wherein the code memory cells having a dielectric block is in a first data state and the code memory cells having a gate dielectric layer is in a second data state.

9. The non-volatile memory structure of claim 8, wherein the gate dielectric layer has a thickness different from the one of the dielectric blocks.

10. The method of claim 8, wherein the gate dielectric layer has a thickness smaller than the one of the dielectric blocks.

11. The method of claim 8, wherein material constituting the long dielectric strip is selected from a group consisting of silicon nitride, silicon oxide and silicon oxy-nitride.
